(19) United States
(12) Patent Application Publication
(10) Pub. No.: US 2024/0347479 A1
(43) Pub. Date: Oct. 17, 2024

(54) SEMICONDUCTOR PACKAGE HAVING MOISTURE PASSING GAP IN POWER OR GROUND METAL PLANE OF A PACKAGE SUBSTRATE

(71) Applicant: MEDIATEK INC., Hsin-chu (TW)

(72) Inventors: Chu-Chia Chang, Hsinchu City (TW); Pei-Haw Tsao, Hsinchu City (TW); Peng-Yu Huang, Hsinchu City (TW); Yu-Liang Hsiao, Hsinchu City (TW); Wei-Fan Chen, Hsinchu City (TW)

(73) Assignee: MEDIATEK INC., Hsin-chu (TW)

(21) Appl. No.: 18/611,681

(22) Filed: Mar. 20, 2024

Related U.S. Application Data
(60) Provisional application No. 63/495,305, filed on Apr. 11, 2023.

(51) Int. Cl. H01L 23/00; H01L 23/31; H01L 23/498

(52) U.S. Cl. CPC H01L 23/564; H01L 23/3128; H01L 23/49816; H01L 23/49822; H01L 24/16; H01L 2224/16227

(57) ABSTRACT

A semiconductor package includes a package substrate having a top surface and an opposing bottom surface. The package substrate includes a top build-up wiring layer and an upper dielectric layer covering the top build-up wiring layer. A semiconductor device and a passive component are mounted on the top surface of the package substrate in a side-by-side manner. A molding compound encapsulates the semiconductor device and the passive component on the top surface of the package substrate. A cavity is disposed between the passive component and the top surface of the package substrate. A moisture passing gap is disposed in the top build-up wiring layer of the package substrate

### CROSS REFERENCE TO RELATED APPLICATIONS

This application claims the benefit of U.S. Provisional Application No. 63/495,305, filed on Apr. 11, 2023. The content of the application is incorporated herein by reference.

### BACKGROUND

The present disclosure relates generally to the field of semiconductor technology, and more particularly, to a semiconductor package having a moisture passing gap in the power or ground metal plane of a package substrate.

Passive components such as capacitors, resistors and inductors play an important role in electronic systems. For example, passive components help smooth signals and improve the performance of the active devices of the system.

Typically, the passive components are mounted on a package substrate and over-molded by a molding compound. A sealed cavity is usually formed between the passive component and the top surface of the package substrate under the mold cap. The sealed cavity is problematic because moisture retained in the cavity may cause reliability issues during the subsequent thermal processes, for example, re-flow processes.

### SUMMARY

It is one object of the present invention to provide a semiconductor package in order to solve the prior art deficiencies or shortcomings.

One aspect of the invention provides a semiconductor package including a package substrate having a top surface and an opposing bottom surface. The package substrate includes a top build-up wiring layer, an upper dielectric layer covering the top build-up wiring layer, a pad layer disposed over the upper dielectric layer on the top surface, and ball pads on the bottom surface. A semiconductor device is mounted on the top surface of the package substrate. A passive component is mounted on the top surface of the package substrate. A molding compound encapsulates the semiconductor device and the passive component on the top surface of the package substrate. A cavity is disposed between the passive component and the top surface of the package substrate. A moisture passing gap is disposed in the top build-up wiring layer of the package substrate.

According to some embodiments, the package substrate comprises a ball grid array substrate.

According to some embodiments, the passive component comprises a capacitor, an inductor, or a resistor.

According to some embodiments, terminals of the passive component are electrically connected to respective bonding pads of the pad layer of the package substrate.

According to some embodiments, the top build-up wiring layer functions as a power or ground plane.

According to some embodiments, the moisture passing gap is filled with the upper dielectric layer.

According to some embodiments, the moisture passing gap is aligned with the cavity and moisture retained in the cavity escapes through the moisture passing gap during thermal processes.

According to some embodiments, the moisture passing gap has a width that is smaller than or equal to a width of the passive component.

According to some embodiments, the moisture passing gap has a surface area that is smaller than or equal to a surface area of the passive component.

According to some embodiments, the semiconductor package further includes solder balls mounted on the ball pads, respectively.

Another aspect of the invention provides a semiconductor package including a package substrate having a top surface and an opposing bottom surface. The package substrate includes a top build-up wiring layer, an upper dielectric layer covering the top build-up wiring layer, at least one inner insulating layer, at least one inner metal wiring layer, a pad layer disposed over the upper dielectric layer on the top surface, and ball pads on the bottom surface. A semiconductor device is mounted on the top surface of the package substrate. A passive component is mounted on the top surface of the package substrate. A molding compound encapsulates the semiconductor device and the passive component on the top surface of the package substrate. A cavity is disposed between the passive component and the top surface of the package substrate. A first moisture passing gap is disposed in the top build-up wiring layer of the package substrate. A second moisture passing gap is disposed in the at least one inner metal wiring layer of the package substrate.

According to some embodiments, the package substrate comprises a ball grid array substrate.

According to some embodiments, the passive component comprises a capacitor, an inductor, or a resistor.

According to some embodiments, terminals of the passive component are electrically connected to respective bonding pads of the pad layer of the package substrate.

According to some embodiments, the top build-up wiring layer functions as a power or ground plane.

According to some embodiments, the first moisture passing gap is filled with the upper dielectric layer.

According to some embodiments, the first moisture passing gap is aligned with the cavity and moisture retained in the cavity escapes through the moisture passing gap during thermal processes.

According to some embodiments, the first moisture passing gap has a width that is smaller than or equal to a width of the passive component, and the second moisture passing gap has a width that is smaller than or equal to the width of the passive component.

According to some embodiments, the first moisture passing gap has a surface area that is smaller than or equal to a surface area of the passive component.

According to some embodiments, the semiconductor package further includes solder balls mounted on the ball pads, respectively.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the invention and are incorporated in and constitute a part of this specification. The drawings illustrate embodiments of the invention and, together with the description, serve to explain the principles of the invention. In the drawings:

FIG. 1 is a schematic, cross-sectional diagram showing an exemplary semiconductor package in accordance with one embodiment of the invention; and

FIG. 2 is a schematic, cross-sectional diagram showing an exemplary semiconductor package in accordance with another embodiment of the invention.

### DETAILED DESCRIPTION

In the following detailed description of embodiments of the invention, reference is made to the accompanying drawings, which form a part hereof, and in which is shown by way of illustration specific preferred embodiments in which the disclosure may be practiced.

These embodiments are described in sufficient detail to enable those skilled in the art to practice them, and it is to be understood that other embodiments may be utilized and that mechanical, chemical, electrical, and procedural changes may be made without departing from the spirit and scope of the present disclosure. The following detailed description is, therefore, not to be taken in a limiting sense, and the scope of embodiments of the present invention is defined only by the appended claims.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

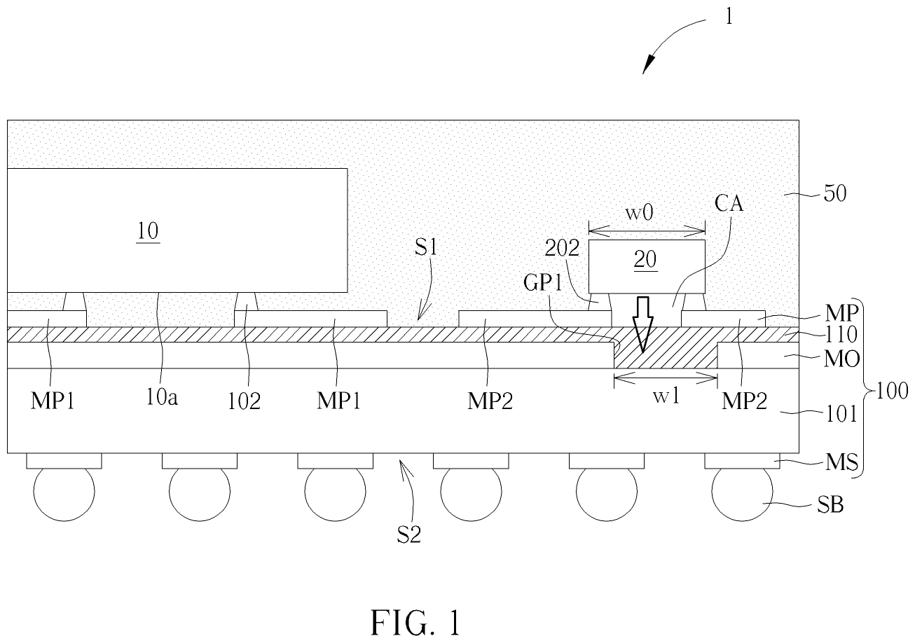

Please refer to FIG. 1. FIG. 1 is a schematic, cross-sectional diagram showing an exemplary semiconductor package in accordance with one embodiment of the invention. As shown in FIG. 1, the semiconductor package 1 comprises a package substrate 100, for example, a ball grid array (BGA) substrate. The package substrate 100 has a top surface S1 and an opposing bottom surface S2. According to an embodiment, the package substrate 100 may include, but not limited to, a core 101, a top build-up wiring layer MO, an upper dielectric layer 110 covering the top build-up wiring layer MO, a pad layer MP disposed over the upper dielectric layer 110 on the top surface S1, and ball pads MS on the bottom surface S2. According to an embodiment, solder balls or BGA balls SB may be mounted on the ball pads MS, respectively.

According to an embodiment, for example, the core 101 may comprise a copper clad laminate, but is not limited thereto. According to an embodiment, for example, the top build-up wiring layer MO may be a power plane or a ground plane. It is understood that in some embodiments the package substrate 100 may a coreless substrate.

According to an embodiment, a semiconductor device 10 such as a semiconductor chip or die is mounted on the top surface S1 of the package substrate 100 in a flip chip fashion. According to an embodiment, the active side 10a of the semiconductor device 10 may be directly connected to the respective bonding pads MP1 of the pad layer MP through connecting elements 102 such as solder bumps, metal pillars, micro-bumps or the like. In some embodiments, the semiconductor device 10 may be mounted on the top surface S1 in a wire bonding fashion.

According to an embodiment, a passive component 20 is mounted on the top surface S1 of the package substrate 100. The passive component 20 may be disposed in proximity to the semiconductor device 10. According to an embodiment, for example, the passive component 20 may comprise a capacitor, an inductor, or a resistor, but is not limited thereto. According to an embodiment, the terminals of the passive component 20 may be electrically connected to the respective bonding pads MP2 of the pad layer MP of the package substrate 100.

According to an embodiment, a molding compound 50 encapsulates the semiconductor device 10 and the passive component 20. According to an embodiment, the passive component 20 is over-molded and a sealed cavity CA is formed between the passive component 20 and the top surface S1 of the package substrate 100. The cavity CA becomes a concern because moisture retained in the cavity CA may cause reliability problems during the subsequent thermal processes, for example, re-flow processes. The instant disclosure addresses this issue.

According to an embodiment, a moisture passing gap GP1 is provided in the top build-up wiring layer MO that may function as a power or ground plane. According to an embodiment, the moisture passing gap GP1 may be filled with the upper dielectric layer 110. According to an embodiment, the moisture passing gap GP1 is generally aligned with the cavity CA such that moisture retained in the cavity CA can easily escape along the path as indicated by the arrow during the subsequent thermal processes. According to an embodiment, the moisture passing gap GP1 is disposed directly under the passive component 20.

According to an embodiment, for example, the moisture passing gap GP1 has a width w1 that is smaller than or equal to a width w0 of the passive component 20. According to an embodiment, when viewed from the above, the moisture passing gap GP1 has a surface area that is smaller than or equal to a surface area of the passive component 20 in order not to affect the signal integrity of the power or ground plane.

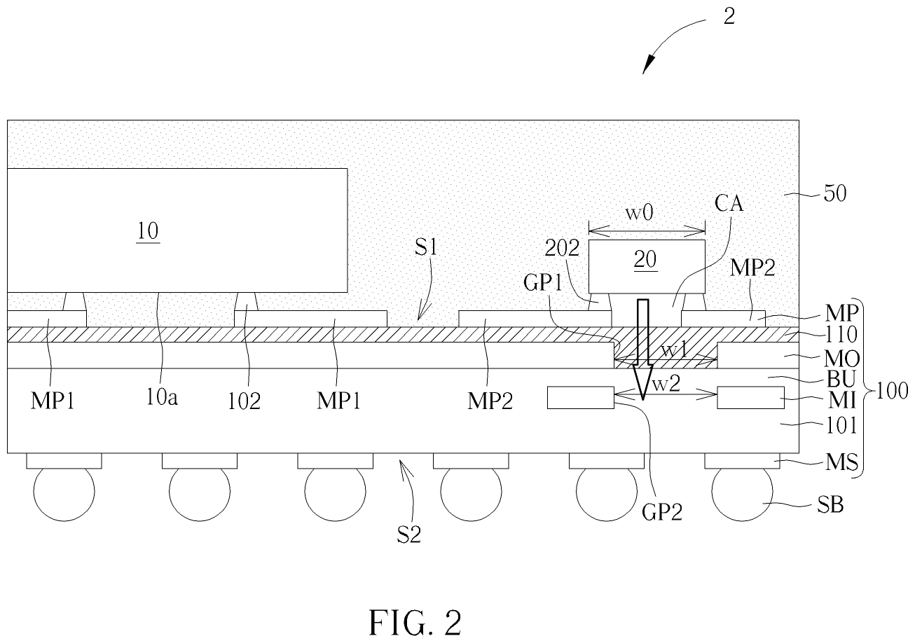

Please refer to FIG. 2. FIG. 2 is a schematic, cross-sectional diagram showing an exemplary semiconductor package in accordance with another embodiment of the invention. As shown in FIG. 2, likewise, the semiconductor package 2 comprises a package substrate 100, for example, a ball grid array substrate. The package substrate 100 has a top surface S1 and an opposing bottom surface S2. According to an embodiment, the package substrate 100 may include, but not limited to, a core 101, a top build-up wiring layer MO, an upper dielectric layer 110 covering the top build-up wiring layer MO, a pad layer MP disposed over the upper dielectric layer 110 on the top surface S1, and ball pads MS on the bottom surface S2. According to an embodiment, solder balls or BGA balls SB may be mounted on the ball pads MS, respectively.

According to an embodiment, the package substrate 100 may further comprise at least one insulating layer BU and at least one inner metal wiring layer MI. According to an embodiment, for example, the core 101 may comprise a copper clad laminate, but is not limited thereto. According to an embodiment, for example, the top build-up wiring layer MO may be a power plane or a ground plane. It is understood that in some embodiments the package substrate 100 may a coreless substrate.

According to an embodiment, a semiconductor device 10 such as a semiconductor chip or die is mounted on the top surface S1 of the package substrate 100 in a flip chip fashion. According to an embodiment, the active side 10a of the semiconductor device 10 may be directly connected to the respective bonding pads MP1 of the pad layer MP through connecting elements 102 such as solder bumps, metal pillars, micro-bumps or the like. In some embodiments, the semiconductor device 10 may be mounted on the top surface S1 in a wire bonding fashion.

According to an embodiment, a passive component 20 is mounted on the top surface S1 of the package substrate 100. The passive component 20 may be disposed in proximity to the semiconductor device 10. According to an embodiment, for example, the passive component 20 may comprise a capacitor, an inductor, or a resistor, but is not limited thereto. According to an embodiment, the terminals of the passive component 20 may be electrically connected to the respective bonding pads MP2 of the pad layer MP of the package substrate 100.

According to an embodiment, a molding compound 50 encapsulates the semiconductor device 10 and the passive component 20. According to an embodiment, the passive component 20 is over-molded and a sealed cavity CA is formed between the passive component 20 and the top surface S1 of the package substrate 100. According to an embodiment, a first moisture passing gap GP1 is provided in the top build-up wiring layer MO. According to an embodiment, the first moisture passing gap GP1 may be filled with the upper dielectric layer 110. According to an embodiment, a second moisture passing gap GP2 is provided in the inner metal wiring layer MI.

According to an embodiment, the first moisture passing gap GP1 and the second moisture passing gap GP2 may be aligned with the cavity CA such that moisture retained in the cavity CA can easily escape along the path as indicated by the arrow during the subsequent thermal processes.

According to an embodiment, for example, the first moisture passing gap GP1 has a width w1 that is smaller than or equal to a width w0 of the passive component 20. According to an embodiment, for example, the second moisture passing gap GP2 has a width w2 that is smaller than or equal to a width w0 of the passive component 20. According to an embodiment, when viewed from the above, the first moisture passing gap GP1 has a surface area that is smaller than or equal to a surface area of the passive component 20.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor package, comprising:
a package substrate having a top surface and an opposing bottom surface, wherein the package substrate comprises a top build-up wiring layer, an upper dielectric layer covering the top build-up wiring layer, a pad layer disposed over the upper dielectric layer on the top surface, and ball pads on the bottom surface;
a semiconductor device mounted on the top surface of the package substrate;
a passive component mounted on the top surface of the package substrate;
a molding compound encapsulating the semiconductor device and the passive component on the top surface of the package substrate;
a cavity disposed between the passive component and the top surface of the package substrate; and
a moisture passing gap disposed in the top build-up wiring layer of the package substrate.

2. The semiconductor package according to claim 1, wherein the package substrate comprises a ball grid array substrate.

3. The semiconductor package according to claim 1, wherein the passive component comprises a capacitor, an inductor, or a resistor.

4. The semiconductor package according to claim 1, wherein terminals of the passive component are electrically connected to respective bonding pads of the pad layer of the package substrate.

5. The semiconductor package according to claim 1, wherein the top build-up wiring layer functions as a power or ground plane.

6. The semiconductor package according to claim 1, wherein the moisture passing gap is filled with the upper dielectric layer.

7. The semiconductor package according to claim 1, wherein the moisture passing gap is aligned with the cavity and moisture retained in the cavity escapes through the moisture passing gap during thermal processes.

8. The semiconductor package according to claim 1, wherein the moisture passing gap has a width that is smaller than or equal to a width of the passive component.

9. The semiconductor package according to claim 1, wherein the moisture passing gap has a surface area that is smaller than or equal to a surface area of the passive component.

10. The semiconductor package according to claim 1 further comprising:
solder balls mounted on the ball pads, respectively.

11. A semiconductor package, comprising:
a package substrate having a top surface and an opposing bottom surface, wherein the package substrate comprises a top build-up wiring layer, an upper dielectric layer covering the top build-up wiring layer, at least one inner insulating layer, at least one inner metal wiring layer, a pad layer disposed over the upper dielectric layer on the top surface, and ball pads on the bottom surface;
a semiconductor device mounted on the top surface of the package substrate;
a passive component mounted on the top surface of the package substrate;
a molding compound encapsulating the semiconductor device and the passive component on the top surface of the package substrate;
a cavity disposed between the passive component and the top surface of the package substrate;
a first moisture passing gap disposed in the top build-up wiring layer of the package substrate; and
a second moisture passing gap disposed in the at least one inner metal wiring layer of the package substrate.

12. The semiconductor package according to claim 11, wherein the package substrate comprises a ball grid array substrate.

13. The semiconductor package according to claim 11, wherein the passive component comprises a capacitor, an inductor, or a resistor.

14. The semiconductor package according to claim 11, wherein terminals of the passive component are electrically connected to respective bonding pads of the pad layer of the package substrate.

15. The semiconductor package according to claim 11, wherein the top build-up wiring layer functions as a power or ground plane.

16. The semiconductor package according to claim 11, wherein the first moisture passing gap is filled with the upper dielectric layer.

17. The semiconductor package according to claim 11, wherein the first moisture passing gap is aligned with the cavity and moisture retained in the cavity escapes through the moisture passing gap during thermal processes.

18. The semiconductor package according to claim 11, wherein the first moisture passing gap has a width that is smaller than or equal to a width of the passive component, and the second moisture passing gap has a width that is smaller than or equal to the width of the passive component.

19. The semiconductor package according to claim 11, wherein the first moisture passing gap has a surface area that is smaller than or equal to a surface area of the passive component.

20. The semiconductor package according to claim 11 further comprising:
solder balls mounted on the ball pads, respectively.
